(19) United States
(12) Patent Application Publication
(10) Pub. No.: US 2024/0165659 A1
(43) Pub. Date: May 23, 2024

(54) METHODS OF PROCESSING WORKPIECES USING ORGANIC RADICALS

(71) Applicants: Beijing E-Town Semiconductor Technology Co., Ltd., Beijing (CN); Mattson Technology, Inc., Fremont, CA (US)

(72) Inventors: Ting Xie, Fremont, CA (US); Binhui Hu, Milpitas, CA (US); Haichun Yang, San Jose, CA (US)

(21) Appl. No.: 18/514,719

(22) Filed: Nov. 20, 2023

Related U.S. Application Data
(60) Provisional application No. 63/427,220, filed on Nov. 22, 2022.

(51) Int. Cl. B05D 1/00; B05D 7/24

(52) U.S. Cl. CPC B05D 1/62; B05D 7/24

(57) ABSTRACT

Processes treating a workpiece are provided. In one example implementation, a method can include performing an organic radical treatment process on a workpiece. The workpiece includes a photoresist material and a semiconductor material. The organic radical treatment process can include generating one or more species in a first chamber. The treatment process can include flowing one or more hydrocarbon molecules at a flow rate of about 100 sccm to about 15000 sccm into the one or more species to create a mixture. The mixture can include one or more organic radicals. The treatment process can include exposing the workpiece to the mixture in a second chamber. The mixture etches the photoresist material at an etch rate that is greater than an etch rate of the semiconductor material. Devices and systems for processing workpieces are also provided.

### RELATED APPLICATIONS

The present application claims the benefit of priority to U.S. Provisional Application No. 63/427,220, titled “METHODS OF PROCESSING WORKPIECES USING ORGANIC RADICALS,” filed Nov. 22, 2022, which is incorporated herein by reference for all purposes.

### FIELD

The present disclosure relates generally to an organic radical treatment process for a workpiece.

### BACKGROUND

Plasma processing is widely used in the semiconductor industry for deposition, etching, resist removal, and related processing of semiconductor wafers and other substrates. Plasma sources (e.g., microwave, ECR, inductive, etc.) are often used for plasma processing to produce high density plasma and reactive species for processing substrates. Post-implantation photoresist, post-etch residue, and other mask and/or material removal have been accomplished using plasma dry strip processes. In plasma dry strip processes, neutral particles from a plasma generated in a remote plasma chamber pass through a separation grid into a processing chamber to treat a substrate, such as a semiconductor wafer.

### SUMMARY

Aspects and advantages of embodiments of the present disclosure will be set forth in part in the following description, or may be learned from the description, or may be learned through practice of the embodiments.

One example aspect of the present disclosure is directed to a method for processing a workpiece. The workpiece can include a photoresist material and a semiconductor material. In one example implementation, a method can include performing an organic radical treatment process on a workpiece. The organic radical treatment process can include generating one or more species in a first chamber. The treatment process can include flowing a hydrocarbon containing gas having one or more hydrocarbon molecules into the species. The hydrocarbon gas is flowed at a flow rate of from about 100 sccm to about 15,000 sccm into the one or more species to create a mixture including one or more organic radicals. The treatment process can include exposing the photoresist material and the semiconductor material on the workpiece to the mixture in a second chamber. The mixture etches the photoresist material at an etch rate that is greater than an etch rate of the semiconductor material.

Other example aspects of the present disclosure are directed to systems, methods, and apparatus for treatment of workpieces.

These and other features, aspects and advantages of various embodiments will become better understood with reference to the following description and appended claims. The accompanying drawings, which are incorporated in and constitute a part of this specification, illustrate embodiments of the present disclosure and, together with the description, serve to explain the related principles.

### BRIEF DESCRIPTION OF THE DRAWINGS

Detailed discussion of embodiments directed to one of ordinary skill in the art are set forth in the specification, which makes reference to the appended figures, in which:

FIG. 1 depicts an example treatment process according to conventional techniques;

FIG. 2 depicts an example treatment process according to example aspects of the present disclosure;

FIG. 3 depicts an example plasma processing apparatus according to example embodiments of the present disclosure;

FIG. 4 depicts example post plasma gas injection during a treatment process according to example embodiments of the present disclosure;

FIG. 5 depicts example post plasma gas injection during a treatment process according to example embodiments of the present disclosure;

FIG. 6 depicts a flow diagram of an example treatment process according to example embodiments of the present disclosure;

FIG. 7 depicts a flow diagram of an example treatment process according to example embodiments of the present disclosure;

FIG. 8 depicts an example plasma processing apparatus according to example embodiments of the present disclosure; and

FIG. 9 depicts an example plasma processing apparatus according to example embodiments of the present disclosure.

### DETAILED DESCRIPTION

Reference now will be made in detail to embodiments, one or more examples of which are illustrated in the drawings. Each example is provided by way of explanation of the embodiments, not limitation of the present disclosure. In fact, it will be apparent to those skilled in the art that various modifications and variations can be made to the embodiments without departing from the scope or spirit of the present disclosure. For instance, features illustrated or described as part of one embodiment can be used with another embodiment to yield a still further embodiment. Thus, it is intended that aspects of the present disclosure cover such modifications and variations.

The complexity of stripping photoresist materials from the surface of a workpiece has increased given reduced device dimensions and requirement for material loss control during the photoresist strip process. Further, during a photoresist strip process, multiple materials on the workpiece can be exposed. For instance, while hydrogen strip processes are known for removing photoresist from a workpiece, such process cause significant damage to other materials on the workpiece, such as semiconductor materials (e.g., silicon or silicon germanium) or other low-k dielectric materials. For instance, hydrogen processes used to strip photoresist can severely damage silicon or silicon germanium by forming a SiH₄ byproduct.

Accordingly, example aspects of the present disclosure are directed to treatment processes for etching photoresist materials, while concurrently passivating semiconductor materials on the workpiece. For instance, the present treatment processes can include exposing the workpiece to one or more organic radicals to simultaneously strip photoresist from the workpiece and to passivate other semiconductor materials on the workpiece. As such, the photoresist material can be selectively stripped from the workpiece.

Aspects of the present disclosure provide a number of technical effects and benefits. For instance, the treatment processes disclosed herein allow for selective strip of photoresist materials without having to utilize hydrogen gas or including only nominal amounts of hydrogen gas. Further, as discovered by the inventors, utilization of a specific flow rate of hydrocarbon molecules (e.g., methane CH₄) according to the flow rates of the present disclosure, can effectively remove photoresist from the workpiece while simultaneously passivating the surfaces of semiconductor materials or other low-k dielectric materials present on the workpiece. As such, additional pre-processing steps or post-processing steps are not required, which reduces both processing time and costs.

Variations and modifications can be made to these example embodiments of the present disclosure. As used in the specification, the singular forms “a,” “and,” and “the” include plural referents unless the context clearly dictates otherwise. The use of “first,” “second,” “third,” etc., are used as identifiers and are not necessarily indicative of any ordering, implied or otherwise. Example aspects may be discussed with reference to a “substrate,” “workpiece,” or “workpiece” for purposes of illustration and discussion. Those of ordinary skill in the art, using the disclosures provided herein, will understand that example aspects of the present disclosure can be used with any suitable workpiece. The use of the term “about” in conjunction with a numerical value refers to within 20% of the stated numerical value.

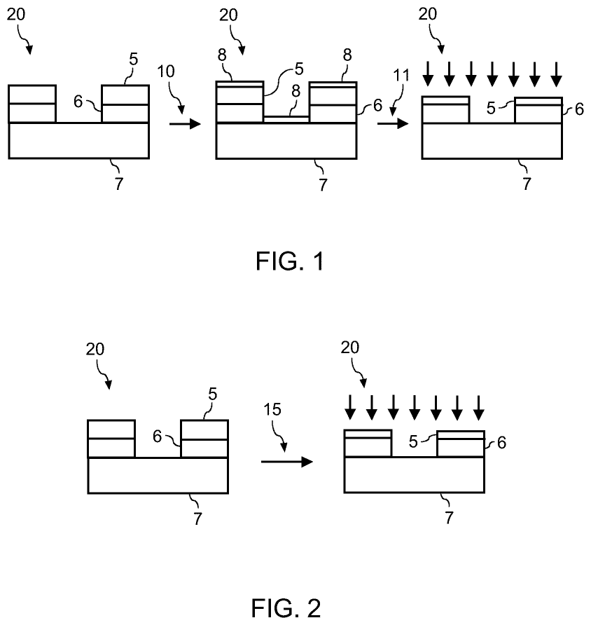

FIG. 1 illustrates an photoresist strip process utilizing a pretreatment step to passivate certain materials (e.g., semiconductor materials) on the workpiece prior to a photoresist strip treatment process. For instance, as shown the workpiece 20 includes a photoresist material 5 and a semiconductor material 6 disposed on a substrate 7. A pretreatment process 10 is performed on the workpiece 20. The pretreatment process 10 generally disposes a passivation layer 8 over certain materials on the workpiece 20. For instance, the pretreatment process 10 can disposed a passivation layer 8 on the photoresist material 5, the semiconductor material 6, and/or the substrate 7. A photoresist etch process 11 is then performed on the workpiece 20 to remove at least a portion (or all of) the photoresist material 5. Notably, such a process requires an additional pretreatment process 10, which requires additional processing time and additional materials for processing (e.g., materials for the passivation layer).

A photoresist etch process according to the present disclosure is provided in FIG. 2. Notably, as shown in FIG. 2, no additional pretreatment process is required. For instance, a treatment process 15 of the present disclosure can be performed on the workpiece to remove photoresist material 5 without damaging the semiconductor material 6 or other materials on the substrate 7. As will be disclosed herein, the pretreatment process 15 of the present disclosure utilizes hydrocarbon radicals to simultaneously passivate semiconductor materials during photoresist etch.

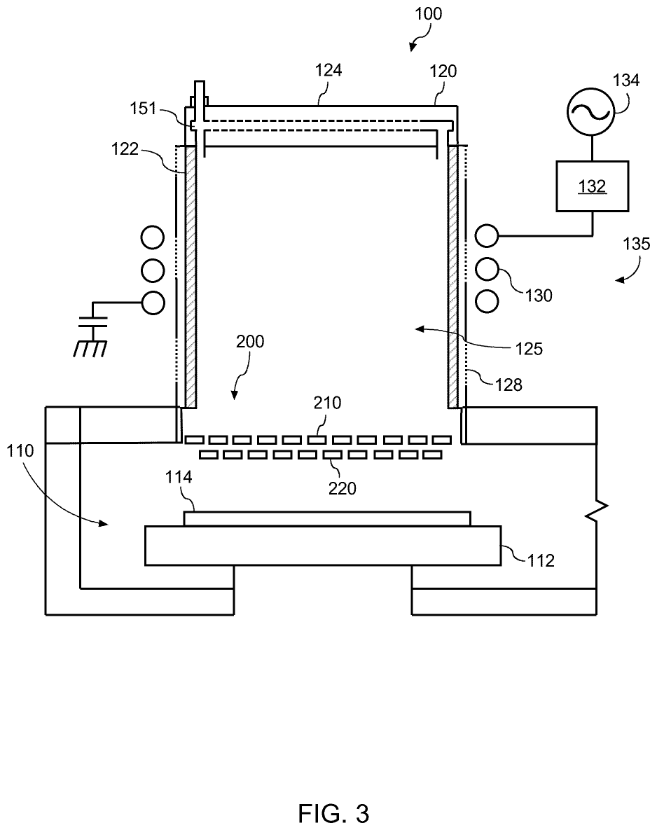

Example embodiments of a processing apparatus suitable for performing the treatment processes of the present disclosure will now be discussed. FIG. 3 depicts an example plasma processing apparatus 100 that can be used to perform treatment processes according to example embodiments of the present disclosure. As illustrated, the plasma processing apparatus 100 includes a processing chamber 110 and a plasma chamber 120 that is separated from the processing chamber 110. The processing chamber 110 includes a substrate holder or pedestal 112 operable to hold a workpiece 114 to be processed, such as a semiconductor wafer. In this example illustration, a plasma is generated in the plasma chamber 120 (i.e., plasma generation region) by an inductively coupled plasma source 135 and desired species are channeled from the plasma chamber 120 to the surface of workpiece 114 through a separation grid assembly 200.

Aspects of the present disclosure are discussed with reference to an inductively coupled plasma source for purposes of illustration and discussion. Those of ordinary skill in the art, using the disclosures provided herein, will understand that any plasma source (e.g., inductively coupled plasma source, capacitively coupled plasma source, etc.) can be used without deviating from the scope of the present disclosure.

The plasma chamber 120 includes a dielectric side wall 122 and a ceiling 124. The dielectric side wall 122, the ceiling 124, and the separation grid 200 define a plasma chamber interior 125. The dielectric side wall 122 can be formed from a dielectric material, such as quartz and/or alumina. The inductively coupled plasma source 135 can include an induction coil 130 disposed adjacent the dielectric side wall 122 about the plasma chamber 120. The induction coil 130 is coupled to an RF power generator 134 through a suitable matching network 132. Process gases (e.g., reactant and/or carrier gases) can be provided to the chamber interior from a gas supply 150 and an annular gas distribution channel 151 or other suitable gas introduction mechanism. When the induction coil 130 is energized with RF power from the RF power generator 134, a plasma can be generated in the plasma chamber 120. In a particular embodiment, the plasma processing apparatus 100 can include an optional grounded Faraday shield 128 to reduce capacitive coupling of the induction coil 130 to the plasma.

As shown in FIG. 3, the separation grid 200 separates the plasma chamber 120 from the processing chamber 110. The separation grid 200 can be used to perform ion filtering from a mixture generated by plasma in the plasma chamber 120 to generate a filtered mixture. The filtered mixture can be exposed to the workpiece 114 in the processing chamber 110.

In some embodiments, the separation grid 200 can be a multi-plate separation grid. For instance, the separation grid 200 can include a first grid plate 210 and a second grid plate 220 that are spaced apart in parallel relationship to one another. The first grid plate 210 and the second grid plate 220 can be separated by a distance.

The first grid plate 210 can have a first grid pattern having a plurality of holes. The second grid plate 220 can have a second grid pattern having a plurality of holes. The first grid pattern can be the same as or different from the second grid pattern. Charged particles can recombine on the walls in their path through the holes of each grid plate 210, 220 in the separation grid 200. Neutrals (e.g., radicals) can flow relatively freely through the holes in the first grid plate 210 and the second grid plate 220. The size of the holes and thickness of each grid plate 210 and 220 can affect transparency for both charged and neutral particles.

In some embodiments, the first grid plate 210 can be made of metal (e.g., aluminum) or other electrically conductive material and/or the second grid plate 220 can be made from either an electrically conductive material or dielectric material (e.g., quartz, ceramic, etc.). In some embodiments, the first grid plate 210 and/or the second grid plate 220 can be made of other materials, such as silicon or silicon carbide. In the event a grid plate is made of metal or other electrically conductive material, the grid plate can be grounded.

One or more controllers (not shown) can be used to control gas flow at various locations on the plasma processing apparatus 100. For instance, one or more controllers can be used to control the gas delivery system 150, which provides gas to the plasma chamber 120. One or more controllers can also be configured to control gas flow for additional gas ports disposed between grid plates of the separation grid 200, embodiments of which will be further discussed hereinbelow.

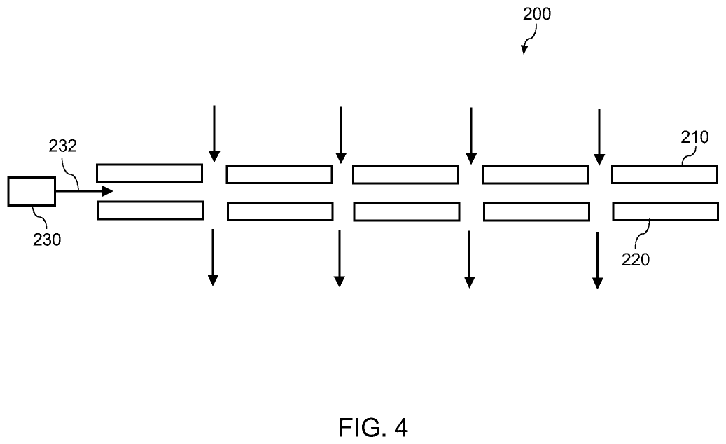

FIG. 4 illustrates an example post plasma gas injection at a separation grid according to example embodiments of the disclosure. FIG. 4 will be discussed with reference to the plasma processing apparatus 100 of FIG. 3 by way of example.

According to example aspects of the present disclosure, the plasma processing apparatus 100 can include one or more gas injection sources 230 configured to inject a gas into the neutral species flowing through the separation grid 200. For instance, a gas injection source 230 can be operable to inject a gas (e.g., a hydrocarbon containing gas) between grid plates in a multi-plate separation grid. In this way, the separation grid can provide post plasma gas injection into the neutral species. The separation grid 200 can be a multi-plate separation grid (e.g., a dual-plate grid (shown in FIG. 3, a three-plate grid, a four-plate grid, etc.). The plasma processing apparatus 100 can include a gas injection source 230 configured to inject a gas 232 between grid plate 210 and grid plate 220, such as in the channel formed between grid plate 210 and grid plate 220. More particularly, the mixture of ions and neutral species generated in the plasma can be exposed to grid plate 210. The gas injection source 230 can inject a gas 232 or other substance into neutral species flowing through the grid plate 210. Neutral species passing through grid plate 220 can be exposed to a workpiece. In some embodiments, the gas injection source 230 can inject a gas 232 directly into the processing chamber 110 at a location below the separation grid and above the surface of the workpiece 114.

The gas 232 or other substance from the gas injection source 230 can be a hydrocarbon containing gas. The hydrocarbon containing gas includes hydrocarbon molecules. Example hydrocarbon molecules can include, for instance, non-cyclic alkanes CₙH₂ₙ₊₂ where n is greater than or equal to one and less than or equal to 10. For instance, the hydrocarbon molecules can include non-cyclic alkanes, such as methane CH₄, ethane C₂H₆, propane or iso-propane C₃H₈, etc. In some embodiments, the hydrocarbon molecules can include cyclic alkanes CₙH₂ₙ, where n is greater than or equal to five and less than or equal to ten. For instance, the hydrocarbon precursor can include cyclic alkanes such as cyclopentane C₅H₁₀, cyclohexane C₆H₁₂, methyl-cyclohexane, C₇H₁₄, dimethyl-cyclohexane C₈H₁₆, 1,3,5-trimethyl-cyclohexane C₉H₁₈, etc. In some embodiments, the hydrocarbon precursors can include alkenes CₙH₂ₙ, where n is greater than or equal to two and less than or equal to ten, such as ethylene C₂H₄, propene C₃H₆, etc.

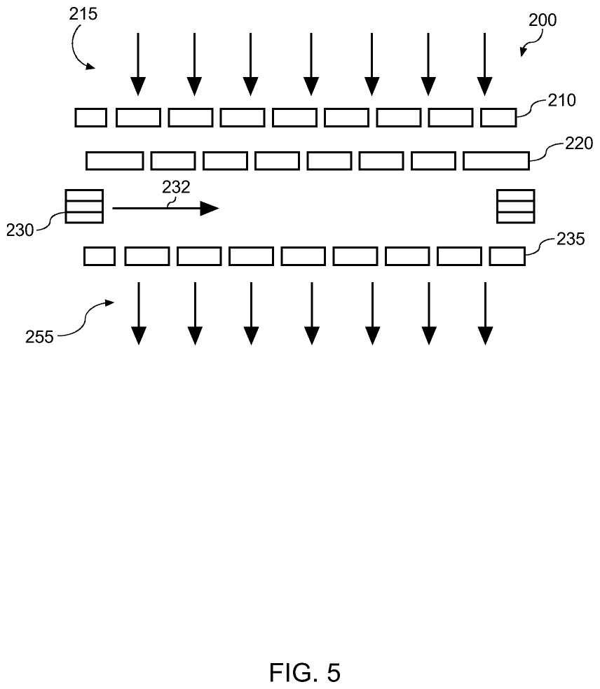

FIG. 5 depicts another example separation grid 200 for injection of hydrocarbon molecules post ion filtering according to example embodiments of the present disclosure. More particularly, the separation grid 200 includes a first grid plate 210 and a second grid plate 220 disposed in parallel relationship for ion/UV filtering.

The first grid plate 210 and a second grid plate 220 can be in parallel relationship with one another. The first grid plate 210 can have a first grid pattern having a plurality of holes. The second grid plate 220 can have a second grid pattern having a plurality of holes. The first grid pattern can be the same as or different from the second grid pattern. Neutral and charged particles 215 from the plasma can be exposed to the separation grid 200. Charged particles (e.g., ions) can recombine on the walls in their path through the holes of each grid plate 210, 220 in the separation grid 200. Neutral species (e.g., radicals or excited inert gas molecules) can flow relatively freely through the holes in the first grid plate 210 and the second grid plate 220.

Subsequent to the second grid plate 220, a gas injection source 230 can be configured to admit hydrocarbon gas into the filtered mixture. Radicals (e.g., CH₃ radicals) 255 resulting from the injection of hydrocarbon gas can pass through a third grid plate 235 for exposure to the workpiece.

The present example is discussed with reference to a separation grid with three grid plates for example purposes. Those of ordinary skill in the art, using the disclosures provided herein, will understand that more or fewer grid plates can be used without deviating from the scope of the present disclosure.

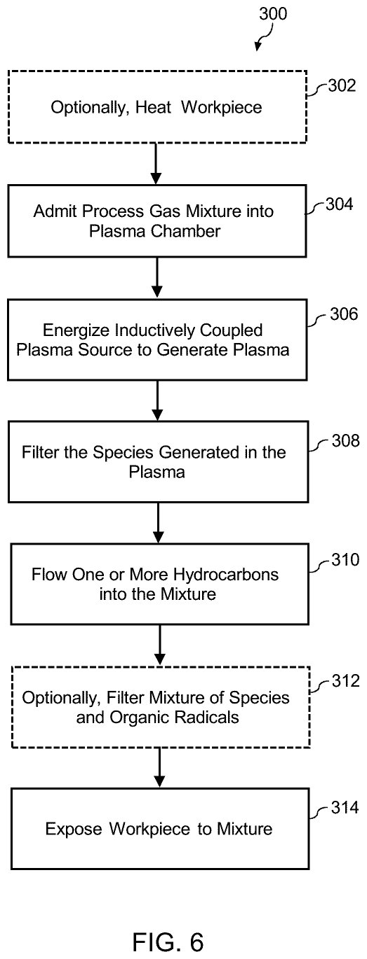

FIG. 6 depicts a flow diagram of an example organic radical treatment process (300) according to example aspects of the present disclosure. The organic radical treatment process (300) can be implemented using the plasma processing apparatus 100. However, as will be discussed in detail below, the organic radical treatment processes according to example aspects of the present disclosure can be implemented using other approaches without deviating from the scope of the present disclosure. FIG. 6 depicts steps performed in a particular order for purposes of illustration and discussion. Those of ordinary skill in the art, using the disclosures provided herein, will understand that various steps of any of the methods described herein can be omitted, expanded, performed simultaneously, rearranged, and/or modified in various ways without deviating from the scope of the present disclosure. In addition, various additional steps (not illustrated) can be performed without deviating from the scope of the present disclosure.

Optionally, at (302), the organic radical treatment process can include heating a workpiece. For instance, the workpiece 114 can be heated in the processing chamber 110 to a process temperature. The workpiece 114 can be heated, for instance, using one or more heating systems associated with the pedestal 112. In some embodiments, the workpiece can be heated to a process temperature in the range of about 100° C. to about 600° C., such as from about 150° ° C. to about 550° C., such as from about 200° ° C. to about 500° ° C., such as from about 250° C. to about 450° C., such as from about 300° ° C. to about 400° C., such as about 300° C.

At (304), the treatment process can include admitting a process gas into a plasma chamber. For instance, a process gas can be admitted into the plasma chamber interior 125 from the gas source 150 via the annular gas distribution channel 151 or other suitable gas introduction mechanism. In some embodiments, the process gas can include an inert gas, such as helium, neon, argon, xenon, and combinations thereof. In certain implementations, the process gas only includes an inert gas and does not include any other gases. In other implementations, however, a second process gas can be admitted to the plasma chamber, such as a reactive gas. In embodiments, the reactive gas can include hydrogen gas (H₂). For instance, the second gas can be admitted into the plasma chamber as part of a process gas forming a mixture. Thus, the process gas can include a mixture including H₂ and helium and/or H₂ and argon and/or H₂ and xenon.

In certain implementations, the process gas can include one or more hydrocarbon molecules. Example hydrocarbon molecules can include, for instance, non-cyclic alkanes CₙH₂ₙ₊₂ where n is greater than or equal to one and less than or equal to 10. For instance, the hydrocarbon molecules can include non-cyclic alkanes, such as methane CH₄, ethane C₂H₆, propane or iso-propane C₃H₈, etc. In some embodiments, the hydrocarbon molecules can include cyclic alkanes CₙH₂ₙ, where n is greater than or equal to five and less than or equal to ten. For instance, the hydrocarbon precursor can include cyclic alkanes such as cyclopentane C₅H₁₀, cyclohexane C₆H₁₂, methyl-cyclohexane, C₇H₁₄, dimethyl-cyclohexane C₈H₁₆, 1,3,5-trimethyl-cyclohexane C₉H₁₈, etc. In some embodiments, the hydrocarbon precursors can include alkenes CₙH₂ₙ, where n is greater than or equal to two and less than or equal to ten, such as ethylene C₂H₄, propene C₃H₆, etc. In certain implementations, the process gas provided to the plasma chamber is substantially free from hydrocarbon molecules.

At (306), the treatment process can include energizing an inductively coupled plasma source to generate a plasma in the plasma chamber from the process gas. For instance, the induction coil 130 can be energized with RF energy from the RF power generator 134 to generate a plasma in the plasma chamber interior 125. In some embodiments, the inductively coupled power source can be energized with pulsed power to obtain desired radicals with reduced plasma energy. The plasma can be used to generate one or more species (e.g., radicals) from the process gas. The species generated from the process gas can include positively charged molecules, negatively charged molecules, neutral molecules, or a combination thereof.

At (308), the treatment process can include filtering the one or more species generated in the plasma chamber. For instance, the one or more ions can be filtered using a separation grid assembly separating the plasma chamber from a processing chamber where the workpiece is located. For instance, the separation grid 200 can be used to filter ions generated by the plasma. The separation grid 200 can have a plurality of holes. Charged particles (e.g., ions) can recombine on the walls in their path through the plurality of holes. Neutral particles (e.g., radicals) can pass through the holes.

In some embodiments, the separation grid 200 can be configured to filter ions with an efficiency greater than or equal to about 90%, such as greater than or equal to about 95%. A percentage efficiency for ion filtering refers to the amount of ions removed from the mixture relative to the total number of ions in the mixture. For instance, an efficiency of about 90% indicates that about 90% of the ions are removed during filtering. An efficiency of about 95% indicates that about 95% of the ions are removed during filtering.

In some embodiments, the separation grid can be a multi-plate separation grid. The multi-plate separation grid can have multiple separation grid plates in parallel. The arrangement and alignment of holes in the grid plate can be selected to provide a desired efficiency for ion filtering, such as greater than or equal to about 95%.

For instance, the separation grid 200 can have a first grid plate 210 and a second grid plate 220 in parallel relationship with one another. The first grid plate 210 can have a first grid pattern having a plurality of holes. The second grid plate 220 can have a second grid pattern having a plurality of holes. The first grid pattern can be the same as or different from the second grid pattern. Charged particles (e.g., ions) can recombine on the walls in their path through the holes of each grid plate 210, 220 in the separation grid 200. Neutral species (e.g., radicals) can flow relatively freely through the holes in the first grid plate 210 and the second grid plate 220.

At (310), the treatment process can include flowing one or more hydrocarbon molecules into the species to create a mixture. For instance, the hydrocarbon molecules can be flowed into the species at a location that is downstream from the plasma chamber. For instance, gas injection ports can be used to flow the hydrocarbon molecules into the mixture. For instance, gas injection ports can be located between the first grid plate 210 and second grid plate 220 of the separation grid 200. Thus, the species can be first filtered by the first grid plate 210 prior to mixing with the hydrocarbon molecules. In other embodiments, a hydrocarbon containing gas can be injected via gas injection source 230 at a location between the second grid plate 220 and a third grid plate 235. Thus, certain of the species will be filtered out prior to introduction of the hydrocarbon molecules. For instance, as noted charged particles (e.g., ions) can be filtered by the separation grid 200 by recombining on the walls of the grid plates in their path through the plurality of holes. Neutral particles (e.g., radicals) can pass through the holes. Accordingly, at the time of injection of the hydrocarbon molecules into the species a certain percentage of charged particles have been filtered out via one or more of the grid plates of the separation grid 200. For instance, in embodiments, at least 50%, such as at least 60%, such as at least 70%, such as at least 80%, such as at least 90%, such as at least 95%, such as at least 99%, of the charged particles have been filtered from the one or more species prior to injection of the hydrocarbon molecules. Post injection, the one or more hydrocarbon molecules can be dissociated by the species to generate organic radicals, such as CH₃ radicals.

The one or more hydrocarbon molecules can be flowed at a flow rate of about 100 sccm to about 15,000 sccm, such as about 200 sccm to about 14,000 sccm, such as about 300 sccm to about 13,000 sccm, such as about 400 sccm to about 12,000 sccm, such as about 500 sccm to about 11,000 sccm, such as about 600 sccm to about 10,000 sccm, such as about 700 sccm to about 9,000 sccm, such as about 800 sccm to about 8,000 sccm, such as about 900 sccm to about 7,000 sccm, such as about 1,000 sccm to about 6,000 sccm, such as about 1,500 sccm to about 5,000 sccm, such as about 2,000 sccm to about 4,000 sccm. In certain embodiments, the hydrocarbon molecules are flowed at a rate of from about 500 sccm to about 700 sccm, such as about 600 sccm. Advantageously, the flow rate of the hydrocarbon gas can influence the amount of hydrocarbon molecules available for dissociation. Thus, too slow of a flow rate for the hydrocarbon molecule containing gas can result in too few radicals (e.g., CH₃) radicals available for passivation and too few hydrogen radicals available for etching photoresist materials. While, too high of a flow of the hydrocarbon containing gas can result in damage to the workpiece.

At (312), the treatment process can include further filtering the mixture of ions and organic radicals (e.g., CH₃ radicals). For instance, as illustrated in FIG. 5, the mixture can be further filtered by a third grid plate 235. While only a third grid plate is shown, additional grid plates could be used to filter the mixture as desired. Additional grid plates (e.g., grid plate 235) can be configured to continue to filter ions with an efficiency greater than or equal to about 90%, such as greater than or equal to about 95%. A percentage efficiency for ion filtering refers to the amount of ions removed from the mixture relative to the total number of ions in the mixture. For instance, an efficiency of about 90% indicates that about 90% of the ions are removed during filtering. An efficiency of about 95% indicates that about 95% of the ions are removed during filtering.

At (314) of FIG. 6, the treatment process can include exposing the workpiece to the mixture. The mixture may also be referred to as a filtered mixture, given that is has been filtered by one or more of the grid plates of the separation grid. More particularly, the workpiece can be exposed to radicals (e.g., CH₃ radicals) generated between the plasma chamber and the process chamber that pass through at least a portion of the separation grid assembly. As an example, organic radicals (e.g., CH₃ radicals) can pass through the separation grid 200 and be exposed on the workpiece 114. In some embodiments, exposing the workpiece to organic radicals can result in attachment of organic radicals on at least a portion of the semiconductor material. Thus, the organic radicals can dispose a passivation layer on semiconductor materials disposed on the workpiece.

Notably, exposing the workpiece to the mixture as disclosed herein also etches photoresist material from the workpiece. For instance, during dissociation of the one or more hydrocarbon molecules, additional hydrogen radicals may be generated, which can strip photoresist materials from the workpiece. Simultaneously, hydrocarbon radicals can passivate semiconductor materials on the workpiece, diminishing or eliminating damage to the semiconductor material. Surprisingly, exposing the workpiece to the mixture can etch the photoresist material at an etch rate that is greater than an etch rate of the semiconductor material(s) on the workpiece. For instance, in embodiments it is contemplated that substantially no portion of the semiconductor material is etched or damaged. For instance, less than about 5%, such as less than about 4%, such as less than about 3%, such as less than about 2%, such as less than about 1% of the semiconductor material is damaged or etched form the workpiece. In other embodiments, the ratio of the etch rate of the photoresist material to the etch rate of the semiconductor material is at about 1.1:1, such as about 1.2:1, such as about 1.5:1, such as about 2:1, such as about 2.5:1, such as about 3:1, such as about 3.5:1, such as about 4:1, such as about 4.5:1 such as about 5:1. In embodiments, the ratio of the etch rate of the photoresist material to the etch rate of the semiconductor material is about 10:1.

Further, the organic radical treatment process can be carried out at varying pressures and power levels. For instance, the organic radical treatment process can be carried out a varying pressures. For instance, the pressure can range from about 100 mT to about 6000 mT, such as from about 200 mT to about 5000 mT, such as from about 300 mT to about 4000 mT, such as from about 400 mT to about 3000 mT, such as from about 500 mT to about 2000 mT, such as from about 600 mT to about 1000 mT. Additionally, the RF source power can range from about 500 watts (“W”) to about 5,000 W, such as from about 600 W to about 4,000 W, such as from about 700 W to about 3,000 W, such as from about 800 W to about 2,000 W, such as from about 900 W to about 1,000 W. Additionally, the workpiece can be exposed to the mixture for a time period ranging from about 100 seconds to about 500 seconds, such as about 150 seconds to about 450 seconds, such as from about 200 seconds to about 300 seconds.

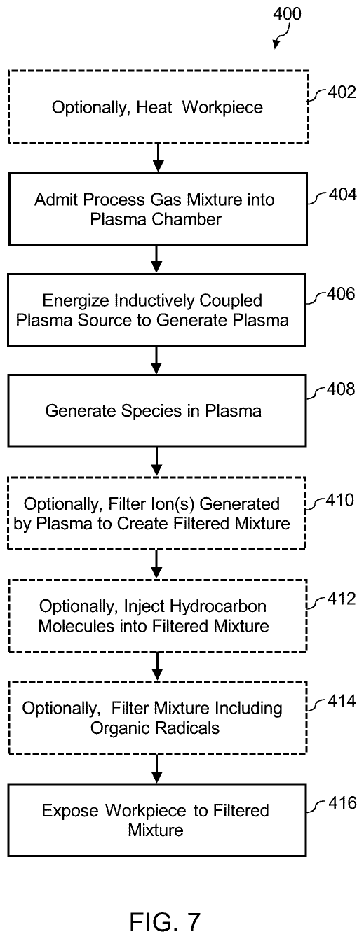

For example, FIG. 7 depicts a flow diagram of an example treatment process (400) according to example embodiments of the present disclosure. The treatment process (400) will be discussed with reference to the plasma processing apparatus 100 of FIG. 3 by way of example. FIG. 7 depicts steps performed in a particular order for purposes of illustration and discussion. Those of ordinary skill in the art, using the disclosures provided herein, will understand that various steps of any of the methods described herein can be omitted, expanded, performed simultaneously, rearranged, and/or modified in various ways without deviating from the scope of the present disclosure. In addition, various steps (not illustrated) can be performed without deviating from the scope of the present disclosure.

Optionally, at (402), the treatment process can include heating a workpiece. For instance, the workpiece 114 can be heated in the processing chamber 110 to a process temperature. The workpiece 114 can be heated, for instance, using one or more heating systems associated with the pedestal 112. In some embodiments, the workpiece can be heated to a temperature in the range of about 100° C. to about 600° C.

At (404), the treatment process can include admitting a process gas mixture into a plasma chamber. For instance, a process gas can be admitted into the plasma chamber interior 125 from the gas source 150 via the annular gas distribution channel 151 or other suitable gas introduction mechanism. In some embodiments, the process gas can include an inert gas, such as helium, argon, neon, xenon, or combinations thereof. In other embodiments, the process gas can include a reactive gas such as H₂ or N₂. Still in other embodiments, the process gas can include a hydrocarbon containing gas. Suitable hydrocarbon containing gases includes those containing hydrocarbon molecules. Example hydrocarbon molecules can include, for instance, non-cyclic alkanes CₙH₂ₙ₊₂ where n is greater than or equal to one and less than or equal to 10. For instance, the hydrocarbon molecules can include non-cyclic alkanes, such as methane CH₄, ethane C₂H₆, propane or iso-propane C₃H₈, etc. The hydrocarbon molecule(s) can include cyclic alkanes CₙH₂ₙ, where n is greater than or equal to five and less than or equal to ten. For instance, the hydrocarbon molecule(s) can include cyclic alkanes such as cyclopentane C₅H₁₀, cyclohexane C₆H₁₂, methyl-cyclohexane, C₇H₁₄, dimethyl-cyclohexane C₈H₁₆, 1,3,5-trimethyl-cyclohexane C₉H₁₈, etc. In some embodiments, the hydrocarbon molecule(s) can include alkenes CₙH₂ₙ, where n is greater than or equal to one and less than or equal to ten, such as ethylene C₂H₄, propene C₃H₆, etc.

At (406), the treatment process can include energizing an inductively coupled plasma source to generate a plasma in the plasma chamber. For instance, the induction coil 130 can be energized with RF energy from the RF power generator 134 to generate a plasma in the plasma chamber interior 125. In some embodiments, the inductively coupled power source can be energized with pulsed power to obtain desired species with reduced plasma energy.

At (408), the treatment process can include generating one or more species in the plasma from the process gas. For instance, a plasma induced in the plasma chamber interior 125 from a process gas (e.g., CH₄) using the inductively coupled plasma source 135 can dissociate molecules in the process gas mixture to generate radicals (e.g., CH₃ radicals) and ions.

Optionally, at (410), the treatment process can include filtering one or more ions generated by the plasma in the mixture to create a filtered mixture. The filtered mixture can include species generated in the plasma from the process gas.

In some embodiments, the one or more ions can be filtered using a separation grid assembly separating the plasma chamber from a processing chamber where the workpiece is located. For instance, the separation grid 200 can be used to filter ions generated by the plasma.

The separation grid 200 can have a plurality of holes. Charged particles (e.g., ions) can recombine on the walls in their path through the plurality of holes. Neutral particles (e.g., radicals) can pass through the holes. In some embodiments, the separation grid 200 can be configured to filter ions with an efficiency greater than or equal to about 90%, such as greater than or equal to about 95%.

In some embodiments, the separation grid can be a multi-plate separation grid. The multi-plate separation grid can have multiple separation grid plates in parallel. The arrangement and alignment of holes in the grid plate can be selected to provide a desired efficiency for ion filtering, such as greater than or equal to about 95%.

Optionally, at (412), additional hydrocarbon molecules can be injected into the filtered mixture. Example hydrocarbon molecules can include, for instance, non-cyclic alkanes CₙH₂ₙ₊₂ where n is greater than or equal to one and less than or equal to 10. For instance, the hydrocarbon molecules can include non-cyclic alkanes, such as methane CH₄, ethane C₂H₆, propane or iso-propane C₃H₈, etc. The hydrocarbon molecule(s) can include cyclic alkanes CₙH₂ₙ, where n is greater than or equal to five and less than or equal to ten. For instance, the hydrocarbon molecule(s) can include cyclic alkanes such as cyclopentane C₅H₁₀, cyclohexane C₆H₁₂, methyl-cyclohexane, C₇H₁₄, dimethyl-cyclohexane C₈H₁₆, 1,3,5-trimethyl-cyclohexane C₉H₁₈, etc. In some embodiments, the hydrocarbon molecule(s) can include alkenes CₙH₂ₙ, where n is greater than or equal to one and less than or equal to ten, such as ethylene C₂H₄, propene C₃H₆, etc.

The hydrocarbon molecules can react with radicals in the species generate desired radicals (e.g., CH₃ radicals). For instance, a hydrocarbon containing gas can be injected into the filtered mixture at a location between the plasma chamber and the processing chamber. For instance, the hydrocarbon molecules can be flowed into the species at a location that is downstream from the plasma chamber. For instance, gas injection ports can be used to flow the hydrocarbon molecules into the mixture. For instance, gas injection ports can be located between the first grid plate 210 and second grid plate 220 of the separation grid 200. Thus, the species can be first filtered by the first grid plate 210 prior to mixing with the hydrocarbon molecules. In other embodiments, a hydrocarbon containing gas can be injected via gas injection source 230 at a location between the second grid plate 220 and a third grid plate 235. Thus, certain of the species will be filtered out prior to introduction of the hydrocarbon molecules. For instance, as noted charged particles (e.g., ions) can be filtered by the separation grid 200 by recombining on the walls of the grid plates in their path through the plurality of holes. Neutral particles (e.g., radicals) can pass through the holes.

The one or more hydrocarbon molecules can be flowed at a flow rate of about 100 sccm to about 15,000 sccm, such as about 200 sccm to about 14,000 sccm, such as about 300 sccm to about 13,000 sccm, such as about 400 sccm to about 12,000 sccm, such as about 500 sccm to about 11,000 sccm, such as about 600 sccm to about 10,000 sccm, such as about 700 sccm to about 9,000 sccm, such as about 800 sccm to about 8,000 sccm, such as about 900 sccm to about 7,000 sccm, such as about 1,000 sccm to about 6,000 sccm, such as about 1,500 sccm to about 5,000 sccm, such as about 2,000 sccm to about 4,000 sccm. In certain embodiments, the hydrocarbon molecules are flowed at a rate of from about 500 sccm to about 700 sccm, such as about 600 sccm.

Optionally, at (414), the treatment process can include further filtering the mixture of ions and organic radicals (e.g., CH₃ radicals). For instance, as illustrated in FIG. 4, the mixture can be further filtered by a third grid plate 235. While only a third grid plate is shown, additional grid plates could be used to filter the mixture as desired. Additional grid plates (e.g., grid plate 235) can be configured to continue to filter ions with an efficiency greater than or equal to about 90%, such as greater than or equal to about 95%. A percentage efficiency for ion filtering refers to the amount of ions removed from the mixture relative to the total number of ions in the mixture. For instance, an efficiency of about 90% indicates that about 90% of the ions are removed during filtering. An efficiency of about 95% indicates that about 95% of the ions are removed during filtering.

At (416) of FIG. 7, the treatment process can include exposing the workpiece to the filtered mixture. More particularly, the workpiece can be exposed to radicals (e.g., CH₃ radicals) generated between the plasma chamber and the process chamber that pass through at least a portion of the separation grid assembly. As an example, organic radicals (e.g., CH₃ radicals) can pass through the separation grid 200 and be exposed on the workpiece 114. In some embodiments, exposing the workpiece to organic radicals can result in attachment of organic radicals on at least a portion of the semiconductor material. Thus, the organic radicals can dispose a passivation layer on semiconductor materials disposed on the workpiece.

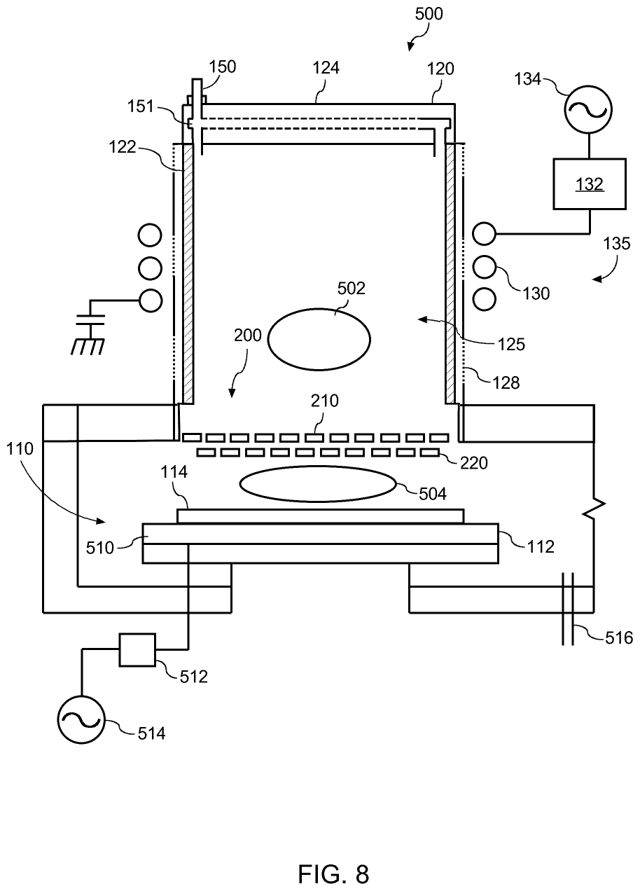

FIG. 8 depicts an example plasma processing apparatus 500 that can be used to implement processes according to example embodiments of the present disclosure. The plasma processing apparatus 500 is similar to the plasma processing apparatus 100 of FIG. 3.

More particularly, plasma processing apparatus 500 includes a processing chamber 110 and a plasma chamber 120 that is separated from the processing chamber 110. Processing chamber 110 includes a substrate holder or pedestal 112 operable to hold a workpiece 114 to be processed, such as a semiconductor wafer. In this example illustration, a plasma is generated in plasma chamber 120 (i.e., plasma generation region) by an inductively coupled plasma source 135 and desired species are channeled from the plasma chamber 120 to the surface of workpiece 114 through a separation grid assembly 200.

The plasma chamber 120 includes a dielectric side wall 122 and a ceiling 124. The dielectric side wall 122, ceiling 124, and separation grid 200 define a plasma chamber interior 125. Dielectric side wall 122 can be formed from a dielectric material, such as quartz and/or alumina. The inductively coupled plasma source 135 can include an induction coil 130 disposed adjacent the dielectric side wall 122 about the plasma chamber 120. The induction coil 130 is coupled to an RF power generator 134 through a suitable matching network 132. Process gases (e.g., an inert gas) can be provided to the chamber interior from gas supply 150 and annular gas distribution channel 151 or other suitable gas introduction mechanism. When the induction coil 130 is energized with RF power from the RF power generator 134, a plasma can be generated in the plasma chamber 120. In a particular embodiment, the plasma processing apparatus 100 can include an optional grounded Faraday shield 128 to reduce capacitive coupling of the induction coil 130 to the plasma.

As shown in FIG. 8, a separation grid 200 separates the plasma chamber 120 from the processing chamber 110. The separation grid 200 can be used to perform ion filtering from a mixture generated by plasma in the plasma chamber 120 to generate a filtered mixture. The filtered mixture can be exposed to the workpiece 114 in the processing chamber.

In some embodiments, the separation grid 200 can be a multi-plate separation grid. For instance, the separation grid 200 can include a first grid plate 210 and a second grid plate 220 that are spaced apart in parallel relationship to one another. The first grid plate 210 and the second grid plate 220 can be separated by a distance.

The first grid plate 210 can have a first grid pattern having a plurality of holes. The second grid plate 220 can have a second grid pattern having a plurality of holes. The first grid pattern can be the same as or different from the second grid pattern. Charged particles can recombine on the walls in their path through the holes of each grid plate 210, 220 in the separation grid. Neutral species (e.g., radicals) can flow relatively freely through the holes in the first grid plate 210 and the second grid plate 220. The size of the holes and thickness of each grid plate 210 and 220 can affect transparency for both charged and neutral particles.

In some embodiments, the first grid plate 210 can be made of metal (e.g., aluminum) or other electrically conductive material and/or the second grid plate 220 can be made from either an electrically conductive material or dielectric material (e.g., quartz, ceramic, etc.). In some embodiments, the first grid plate 210 and/or the second grid plate 220 can be made of other materials, such as silicon or silicon carbide. In the event a grid plate is made of metal or other electrically conductive material, the grid plate can be grounded.

As discussed above, a hydrogen gas can be injected into species passing through the separation grid 200 to generate one or more hydrogen radicals for exposure to the workpiece 114. The hydrogen radicals can be used to implement a variety of semiconductor fabrication processes.

The example plasma processing apparatus 500 of FIG. 8 is operable to generate a first plasma 502 (e.g., a remote plasma) in the plasma chamber 120 and a second plasma 504 (e.g., a direct plasma) in the processing chamber 110. As used herein, a “remote plasma” refers to a plasma generated remotely from a workpiece, such as in a plasma chamber separated from a workpiece by a separation grid. As used herein, a “direct plasma” refers to a plasma that is directly exposed to a workpiece, such as a plasma generated in a processing chamber having a pedestal operable to support the workpiece.

More particularly, the plasma processing apparatus 500 of FIG. 8 includes a bias source having bias electrode 510 in the pedestal 112. The bias electrode 510 can be coupled to an RF power generator 514 via a suitable matching network 512. When the bias electrode 510 is energized with RF energy, a second plasma 504 can be generated from a mixture in the processing chamber 110 for direct exposure to the workpiece 114. The processing chamber 110 can include a gas exhaust port 516 for evacuating a gas from the processing chamber 110. One or more oxygen radicals used in the pretreatment process and/or the hydrogen radicals used in the hydrogen radical treatment process according to example aspects of the present disclosure can be generated using the first plasma 502 and/or the second plasma 504.

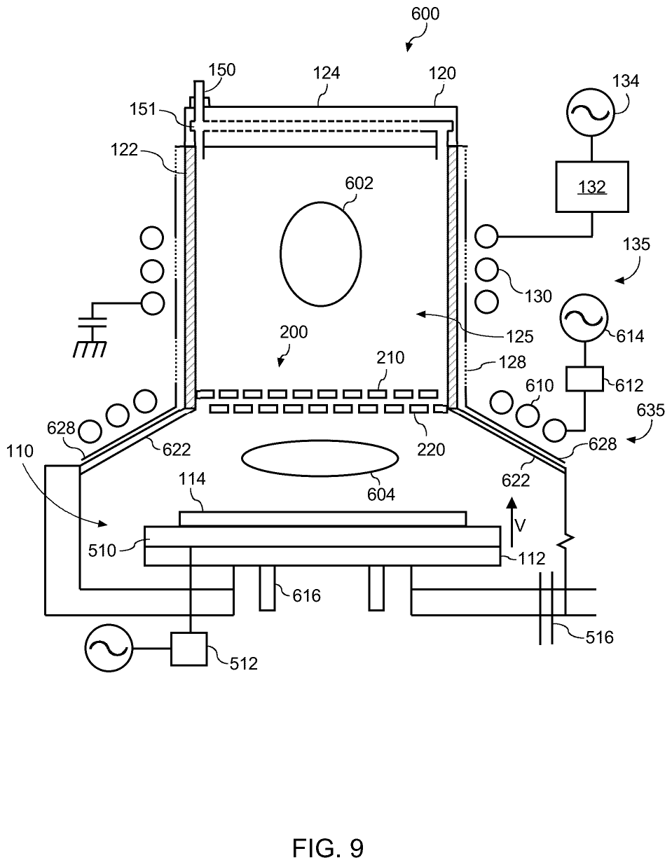

FIG. 9 depicts a processing chamber 600 similar to that of FIG. 3 and FIG. 8. More particularly, plasma processing apparatus 600 includes a processing chamber 110 and a plasma chamber 120 that is separated from the processing chamber 110. Processing chamber 110 includes a substrate holder or pedestal 112 operable to hold a workpiece 114 to be processed, such as a semiconductor wafer. In this example illustration, a plasma is generated in plasma chamber 120 (i.e., plasma generation region) by an inductively coupled plasma source 135 and desired species are channeled from the plasma chamber 120 to the surface of workpiece 114 through a separation grid assembly 200.

The plasma chamber 120 includes a dielectric side wall 122 and a ceiling 124. The dielectric side wall 122, ceiling 124, and separation grid 200 define a plasma chamber interior 125. Dielectric side wall 122 can be formed from a dielectric material, such as quartz and/or alumina. The inductively coupled plasma source 135 can include an induction coil 130 disposed adjacent the dielectric side wall 122 about the plasma chamber 120. The induction coil 130 is coupled to an RF power generator 134 through a suitable matching network 132. Process gas (e.g., an inert gas) can be provided to the chamber interior from gas supply 150 and annular gas distribution channel 151 or other suitable gas introduction mechanism. When the induction coil 130 is energized with RF power from the RF power generator 134, a plasma can be generated in the plasma chamber 120. In a particular embodiment, the plasma processing apparatus 100 can include an optional grounded Faraday shield 128 to reduce capacitive coupling of the induction coil 130 to the plasma.

As shown in FIG. 9, a separation grid 200 separates the plasma chamber 120 from the processing chamber 110. The separation grid 200 can be used to perform ion filtering from a mixture generated by plasma in the plasma chamber 120 to generate a filtered mixture. The filtered mixture can be exposed to the workpiece 114 in the processing chamber.

In some embodiments, the separation grid 200 can be a multi-plate separation grid. For instance, the separation grid 200 can include a first grid plate 210 and a second grid plate 220 that are spaced apart in parallel relationship to one another. The first grid plate 210 and the second grid plate 220 can be separated by a distance.

The first grid plate 210 can have a first grid pattern having a plurality of holes. The second grid plate 220 can have a second grid pattern having a plurality of holes. The first grid pattern can be the same as or different from the second grid pattern. Charged particles can recombine on the walls in their path through the holes of each grid plate 210, 220 in the separation grid. Neutral species (e.g., radicals) can flow relatively freely through the holes in the first grid plate 210 and the second grid plate 220. The size of the holes and thickness of each grid plate 210 and 220 can affect transparency for both charged and neutral particles.

In some embodiments, the first grid plate 210 can be made of metal (e.g., aluminum) or other electrically conductive material and/or the second grid plate 220 can be made from either an electrically conductive material or dielectric material (e.g., quartz, ceramic, etc.). In some embodiments, the first grid plate 210 and/or the second grid plate 220 can be made of other materials, such as silicon or silicon carbide. In the event a grid plate is made of metal or other electrically conductive material, the grid plate can be grounded.

The example plasma processing apparatus 600 of FIG. 9 is operable to generate a first plasma 602 (e.g., a remote plasma) in the plasma chamber 120 and a second plasma 604 (e.g., a direct plasma) in the processing chamber 110. As shown, the plasma processing apparatus 600 can include an angled dielectric sidewall 622 that extends from the vertical sidewall 122 associated with the remote plasma chamber 120. The angled dielectric sidewall 622 can form a part of the processing chamber 110.

A second inductive plasma source 635 can be located proximate the dielectric sidewall 622. The second inductive plasma source 635 can include an induction coil 610 coupled to an RF generator 614 via a suitable matching network 612. The induction coil 610, when energized with RF energy, can induce a direct plasma 604 from a mixture in the processing chamber 110. A Faraday shield 628 can be disposed between the induction coil 610 and the sidewall 622.

The pedestal 112 can be movable in a vertical direction V. For instance, the pedestal 112 can include a vertical lift 616 that can be configured to adjust a distance between the pedestal 112 and the separation grid assembly 200. As one example, the pedestal 112 can be located in a first vertical position for processing using the remote plasma 602. The pedestal 112 can be in a second vertical position for processing using the direct plasma 604. The first vertical position can be closer to the separation grid assembly 200 relative to the second vertical position.

The plasma processing apparatus 600 of FIG. 9 includes a bias source having bias electrode 510 in the pedestal 112. The bias electrode 510 can be coupled to an RF power generator 514 via a suitable matching network 512. The processing chamber 110 can include a gas exhaust port 516 for evacuating a gas from the processing chamber 110. One or more oxygen radicals used in the pretreatment process and/or one or more hydrogen radicals used in the hydrogen radical treatment processes according to example aspects of the present disclosure can be generated using the first plasma 602 and/or the second plasma 604.

Example process parameters for the organic radical treatment process will now be set forth.

### Example 1

Plasma Chamber Process Gas: Ar or He
Post Plasma Gas Injection Gas: CH₄
Process Pressure: about 100-6000 mTorr
Inductively Coupled Plasma Source Power: about 500-5,000 W
Workpiece Temperature: about 100-600° C.
Process Period (time): about 100-500 seconds
Gas Flow Rates for Process Gas:
   Plasma Chamber Process Gas: about 100 sccm to about 15,000 sccm
   Post Plasma Gas Injection Gas: about 500 sccm to about 700 sccm

### Example 2

Plasma Chamber Process Gas: Ar or He combined with H₂ and or CH₄
Post Plasma Gas Injection Gas: none or CH₄
Process Pressure: about 100-6000 mTorr
Inductively Coupled Plasma Source Power: about 500-5,000 W
Workpiece Temperature: about 100-600° C.
Process Period (time): about 100-500 seconds
Gas Flow Rates for Process Gas:
   Plasma Chamber Gas, Ar or He: about 100 sccm to about 15,000 sccm
   Plasma Chamber Gas, H₂: about 100 sccm to about 15,000 sccm
   Plasma Chamber Gas CH₄: about 100 sccm to about 15,000 sccm
   Post Plasma Gas Injection Gas: about 500 sccm to about 700 sccm

While the present subject matter has been described in detail with respect to specific example embodiments thereof, it will be appreciated that those skilled in the art, upon attaining an understanding of the foregoing may readily produce alterations to, variations of, and equivalents to such embodiments. Accordingly, the scope of the present disclosure is by way of example rather than by way of limitation, and the subject disclosure does not preclude inclusion of such modifications, variations and/or additions to the present subject matter as would be readily apparent to one of ordinary skill in the art.

What is claimed is:

1. A method for processing a workpiece, the workpiece comprising photoresist material and a semiconductor material, the method comprising performing an organic radical treatment process on the workpiece, the organic radical treatment process comprising:
generating one or more species by a plasma induced in a process gas in a first chamber;
flowing a hydrocarbon containing gas having one or more hydrocarbon molecules at a flow rate of about 100 sccm to about 15000 sccm into the one or more species to create a mixture, the mixture comprising one or more organic radicals; and
exposing the workpiece to the mixture in a second chamber, wherein the mixture etches the photoresist material at an etch rate that is greater than an etch rate of the semiconductor material.

2. The method of claim 1, wherein the semiconductor material comprises silicon, silicon germanium, or combinations thereof.

3. The method of claim 1, wherein the semiconductor material comprises a low-k dielectric material.

4. The method of claim 1, wherein the one or more organic radicals are generated by dissociating the one or more hydrocarbon molecules in the first chamber.

5. The method of claim 1, wherein the one or more hydrocarbon molecules have a chemical formula of CₙH₂ₙ₊₂, where n is greater than or equal to 1 and less than or equal to 10.

6. The method of claim 1, wherein the one or more hydrocarbon molecules have a chemical formula of CₙH₂ₙ, where n is greater than or equal to 2 and n is less than or equal to 10.

7. The method of claim 1, wherein the one or more organic radicals are generated by reaction of the one or more hydrocarbon molecules with the species.

8. The method of claim 1, wherein the organic radical treatment process results in methylation on at least a portion of the semiconductor material.

9. The method of claim 1, wherein the process gas comprises an inert gas.

10. The method of claim 1, wherein the process gas is substantially free from hydrogen, oxygen, and nitrogen.

11. The method of claim 1, wherein the first chamber is separated from the second chamber by a separation grid.

12. The method of claim 11, wherein flowing one or more hydrocarbon molecules at a flow rate of about 100 sccm to about 15000 sccm into the one or more species to create a mixture comprises flowing the one or more hydrocarbon molecules between a first grid plate and a second grid plate of the separation grid.

13. The method of claim 11, wherein the method comprises filtering one or more ions using the separation grid.

14. The method of claim 11, comprising:
prior to flowing the hydrocarbon containing gas, filtering the one or more species with one or more grid plates of the separation grid; and
subsequent to flowing the hydrocarbon containing gas, filtering the mixture with one or more grid plates of the separation grid.

15. The method of claim 1, wherein the method is carried out at a source power ranging from about 500 W to about 5000 W.

16. The method of claim 1, wherein the method is carried out at a pressure ranging from about 100 mT to about 6000 mT.

17. The method of claim 1, wherein the workpiece is treated at a temperature of ranging from about 100° ° C. to about 600° C.

18. The method of claim 1, wherein the workpiece is exposed to the mixture for a time period ranging from about 100 seconds to about 500 seconds.

19. A system for processing a workpiece comprising:
a plasma chamber separated from a processing chamber via a separation grid, the separation grid having a first grid plate and a second grid plate;
one or more first gas flow injectors configured to flow process gas into the plasma chamber;
an inductively coupled generator configured to generate a plasma from the process gas in the plasma chamber;
one or more second gas flow injectors disposed between the first grid plate and the second grid plate; and
one or more second gas flow controllers configured to flow a hydrocarbon containing gas at a flow rate about 100 sccm to about 15000 sccm via the one or more second gas flow injectors.

20. The system of claim 19, wherein the separation grid comprises a third grid plate and one or more third gas flow injectors disposed between the second grid plate and the third grid plate, and one or more third gas flow controllers configured to flow a hydrocarbon containing gas at a flow rate about 100 sccm to about 15000 sccm via the one or more third gas flow injectors.
